(19) United States
(12) Patent Application Publication
(10) Pub. No.: US 2011/0253037 A1
(43) Pub. Date: Oct. 20, 2011

(54) VACUUM HEATING AND COOLING APPARATUS

(75) Inventors: Koji Tsunekawa, Tokyo (JP); Yoshinori Nagamine, Tokyo (JP); Naoyuki Suzuki, Tokyo (JP); Takuji Okada, Kobe-shi (JP); Shinichi Inaba, Tokyo (JP)

(73) Assignee: CANON ANELVA CORPORATION, Kawasaki-shi (JP)

(21) Appl. No.: 13/093,906

(22) Filed: Apr. 26, 2011

Related U.S. Application Data
(63) Continuation of application No. PCT/JP2010/067873, filed on Oct. 12, 2010.

(30) Foreign Application Priority Data
Oct. 9, 2009 (JP) 2009-234927

(51) Int. Cl. F27D 11/12; H01L 21/00; B05C 11/00; C23C 14/56; B05C 9/14

(52) U.S. Cl. 118/50; 204/298.09; 392/416

(57) ABSTRACT

The vacuum heating and cooling apparatus can rapidly heat and cool only the substrate after film-forming treatment while maintaining high vacuum. The temperature rise of members in the chamber with time caused by accumulation of heat is suppressed, and the variation of temperature between substrates is decreased. In an embodiment, the heating and cooling apparatus for heating and cooling a substrate in a vacuum, includes: a vacuum chamber; a radiation energy source positioned at the vacuum chamber on an atmosphere side for emitting a heating light; an incidence part for causing the heating light from the radiation energy source to enter the vacuum chamber; a substrate-holding member for holding the substrate; and a substrate-transfer mechanism for transferring the substrate held by the substrate-holding member in a heating state to a heating position proximal to the radiation energy source, and transferring the substrate and the substrate-holding member in a non-heating state to a non-heating position distant from the radiation energy source, wherein the substrate-holding member has a plate shape for placing the substrate thereon and has an outer shape larger than that of the incidence part for causing the heating light to enter the vacuum chamber.

### CROSS-REFERENCES TO RELATED APPLICATIONS

This application is a continuation application of International Application No. PCT/JP2010/067873, filed Oct. 12, 2010, which claims the benefit of Japanese Patent Application No. 2009-234927, filed Oct. 9, 2009. The contents of the aforementioned applications are incorporated herein by reference in their entities.

### TECHNICAL FIELD

The present invention relates to a vacuum heating and cooling apparatus which rapidly heats and cools a substrate for a semiconductor device, an electronic device, a magnetic device, a display device, and the like in vacuum.

### BACKGROUND ART

A tunnel magnetoresistance element having an MgO tunnel barrier layer, used as a sensor element of a magnetic random access memory (MRAM) and a magnetic head has a structure of laminating a plurality of metal films (magnetic film and non-magnetic film) and insulating films (such as MgO tunnel barrier layer). That type of magnetoresistance element is deposited by sputtering method excellent in productivity, followed by heat treatment in a separate apparatus (magnetic field heat treatment furnace) while applying high magnetic field of 1 Tesla or more, (refer to Non-Patent Document 1).

The method of forming the MgO tunnel barrier layer is disclosed as, for example, the method of directly performing sputter deposition of a MgO target by the RF sputtering method, (refer to Patent Document 1), the method of forming a metal Mg film, and then forming a metal Mg film in oxygen atmosphere by the reactive sputtering method, followed by applying oxidation treatment, (refer to Patent Document 2), the method of forming a metal Mg film, and then applying oxidation treatment, followed by once again forming a metal Mg film, (refer to Patent Document 3), and the method of forming a metal Mg film, and then applying oxidation treatment, followed by applying heat treatment, further by again forming a metal Mg, and finally applying oxidation treatment, (refer to Patent Document 4).

There is a method of forming the MgO tunnel barrier layer having further high quality, as disclosed in Non-Patent Document 2, which method enhances crystallization of MgO film by, immediately after applying direct sputter deposition of MgO target by the RF sputtering method, heating the film by irradiating the substrate with infrared light while holding the substrate in a vacuum.

When, as disclosed in Patent Document 4 and Non-Patent Document 2, the heat treatment is applied between depositions, mass production process needs to rapidly cool the substrate after heated down to a temperature suitable for the next deposition (such as room temperature) or in order to stop alteration of film quality such as crystal growth during heating.

Regarding the method of rapidly heating the substrate in a vacuum, the process of forming a semiconductor element includes, as disclosed in Patent Document 5, a method in which the vacuum chamber has a window allowing the heating light to pass therethrough via a vacuum-seal member such as O-ring, thus heating the substrate held in the vacuum chamber by a radiation energy source such as infrared lamp being positioned at the atmosphere side to emit the heating light.

As the method of rapidly cooling the heated substrate, there is a method, as disclosed in Patent Document 6, of cooling the substrate by transferring the substrate into a chamber adjacent to the heating chamber and being thermally isolated from the heating chamber. According to the cooling method, rapid cooling of the substrate is performed by thermal conduction by placing the substrate directly on a cooled substrate-supporting table. As the method of cooling the substrate while leaving the substrate in the heating chamber, not transferring it to the cooling chamber, there is, as disclosed in Patent Document 7, a method in which a cooled gas is introduced into the heating chamber to conduct cooling utilizing the convection of gas. For the method, there is disclosed a technique of increasing the cooling efficiency by inserting a shutter plate to shield the remaining heat of radiation energy source between the radiation energy source and the substrate after completing the heating step.

For the method of further increasing the cooling efficiency, there is a method of applying a heat treatment apparatus, as disclosed in Patent Document 8, which positions a fixed cooling source and a movable cooling plate within the same space as the heating chamber. According to the method disclosed in Patent Document 8, the movable cooling plate is cooled while being positioned to contact with the cooling source during substrate-heating step. And then after completing the substrate-heating step, the movable cooling plate is brought to apart from the cooling source and into contact with the substrate, thus cooling the substrate utilizing the thermal conduction between the substrate and the movable cooling plate.

There is another method, as disclosed in Patent Document 9, of cooling the substrate within the same space as the heating chamber, in which the movable cooling source is brought into contact with the substrate-supporting table containing a heating resistor, thus indirectly cooling the substrate. Furthermore, Patent Documents 10 and 11 disclose similar methods of heating and cooling the substrate by bringing the substrate-supporting table into contact with the heating source and the cooling source.

According to Patent Document 11, the substrate-supporting table itself has the heating and cooling function, and has the electrostatic-attraction function in order to increase the heating and cooling efficiency, and further the substrate-supporting table provided with the electrostatic-attraction function has grooves on a surface contacting with the rear surface of the substrate, to which grooves a gas is introduced to enhance the heat exchange.

As an example of arranging separate heating source and cooling source in a single vacuum chamber to directly heat and cool only the substrate, Patent Document 12 discloses an example of the structure of a load-lock chamber of sputtering apparatus having a mechanism of heating the substrate using the heating light of a lamp heater and having a mechanism of cooling the substrate by bringing the substrate into contact with the substrate-supporting table which is cooled by electrostatic-attraction. According to the example, successive heating and cooling is not the object because the load-lock chamber has both functions. However, heating and cooling are given during evacuation and venting of the load-lock chamber, which shortens the treatment time of sputtering deposition accompanied with the substrate heating.

### DOCUMENTS OF THE PRIOR ART

### Patent Documents

[Patent Document 1] Japanese Patent Laid-Open No. 2006-801165
[Patent Document 2] U.S. Pat. No. 6,841,395
[Patent Document 3] Japanese Patent Laid-Open No. 2007-142424
[Patent Document 4] Japanese Patent Laid-Open No. 2007-173843
[Patent Document 5] Japanese Patent Laid-Open No. 6-13324 (1994)
[Patent Document 6] Japanese Patent Laid-Open No. 5-251377 (1993)
[Patent Document 7] Japanese Patent No. 2886101
[Patent Document 8] Japanese Patent No. 3660254
[Patent Document 9] Published Japanese Translation of PCT Application No. 2002-541428
[Patent Document 10] Japanese Patent Laid-Open No. 2003-318076
[Patent Document 11] Japanese Patent Laid-Open No. 2002-76105
[Patent Document 12] Japanese Patent Laid-Open No. 2003-13215

### Non-Patent Documents

[Non-Patent Document 1] Tsunekawa et al. “Film-forming and Fine working Process of Magnetic Tunnel Junction in Semiconductor Manufacturing Line”, MAGNE Vol. 2, No. 7, pp. 358-363 (2007)
[Non-Patent Document 2] S. Isogami et al. “In-Situ Heat Treatment of Ultrathin MgO Layer for Giant Magnetoresitance Ratio with Low Resistance Area Product in CoFeB/MgO/CoFeB Magnetic Tunnel Junctions”, Applied Physics Letters, 93, 192109 (2008)

### SUMMARY OF INVENTION

Execution of both heating step and cooling step in the same vacuum chamber raises a problem of increase in the temperature of members in the chamber with increase in the number of treating substrates owing to the irradiation of heating light to the member in the chamber at every heating step, thus deteriorating the reproducibility of heating step and cooling step.

The present invention has been made in view of the above problem, and an object thereof is to provide a vacuum heating and cooling apparatus which can conduct rapid heating and rapid cooling of substrate while maintaining high vacuum and can suppress the temperature rise of member in the vacuum chamber with time.

To achieve the above object, the present invention provides a heating and cooling apparatus for heating and cooling a substrate in a vacuum, comprising: a vacuum chamber; a radiation energy source positioned at the vacuum chamber on an atmosphere side configured so as to emit a heating light; an incidence part configured so as to cause the heating light from the radiation energy source to enter the vacuum chamber; a substrate-holding member configured so as to hold the substrate; and a transfer mechanism configured so as to transfer, in a heating state, the substrate held by the substrate-holding member to a heating position proximal to the radiation energy source, and to transfer, in a non-heating state, the substrate and the substrate-holding member to a non-heating position distant from the radiation energy source, wherein the substrate-holding member has a plate-like shape for placing the substrate thereon and has an outer shape larger than that of the incidence part for causing the heating light to enter the vacuum chamber.

The present invention suppresses the temperature rise of the members in the vacuum chamber with time, thus allowing stable heating and cooling the substrates with good reproducibility therebetween even when successive heating and cooling treatments are given.

### BRIEF DESCRIPTION OF THE DRAWINGS

FIG. 1 illustrates the structure of vacuum heating and cooling apparatus in an embodiment of the present invention.

FIG. 2A illustrates a plan view showing the positional relation of a substrate at a heating position and peripheral members in an embodiment of the present invention.

FIG. 2B illustrates an A-A′ section of FIG. 2A.

FIG. 3A illustrates a plan view showing the positional relation of the substrate at the transferring position and the peripheral members in an embodiment of the present invention.

FIG. 3B illustrates a B-B′ section of FIG. 3A.

FIG. 4A illustrates a plan view showing the positional relation of the substrate and the peripheral members immediately before picking-up the substrate in an embodiment of the present invention.

FIG. 4B illustrates a C-C′ section of FIG. 4A.

FIG. 5A illustrates a plan view showing the positional relation of the substrate and the peripheral members immediately after picking-up the substrate in an embodiment of the present invention.

FIG. 5B illustrates a D-D′ section of FIG. 5A.

FIG. 6A illustrates a plan view showing the positional relation of the substrate and the peripheral members at completion of transfer in an embodiment of the present invention.

FIG. 6B illustrates E-E′ section of FIG. 6A.

FIG. 7 illustrates the structure of sputtering apparatus joined with the vacuum heating and cooling apparatus in an embodiment of the present invention.

FIG. 8 illustrates the block diagram of rough structure of a control system of the vacuum heating and cooling apparatus in an embodiment of the present invention.

FIG. 9 illustrates the structure of vacuum heating and cooling apparatus of an embodiment of the present invention.

FIG. 10 illustrates the positional relation of the peripheral members in a state of preparing for carrying-in of the substrate in an embodiment of the present invention.

FIG. 11 illustrates the positional relation of the peripheral members on carrying-in of the substrate in an embodiment of the present invention.

FIG. 12 illustrates the positional relation of the substrate and the peripheral members at completion of carrying-in of the substrate and at completion of preparation for carrying-out thereof in an embodiment of the present invention.

FIG. 13 illustrates the positional relation of the substrate and the peripheral members at the heating position in an embodiment of the present invention.

FIG. 14 illustrates the positional relation of the substrate and the peripheral members at the cooling position in an embodiment of the present invention.

FIG. 15 illustrates the positional relation of a ring-shaped substrate-holding member and the cooling member on heating the substrate in an embodiment of the present invention.

FIG. 16 illustrates the positional relation of the ring-shaped substrate-holding member and the cooling member on cooling the substrate in an embodiment of the present invention.

FIG. 17 illustrates a cooling member having two-stage structure in an embodiment of the present invention.

FIG. 18 illustrates a substrate-supporting part erected on the substrate-holding member in an embodiment of the present invention.

FIG. 19A illustrates a plan view showing the position of the substrate-holding member in a state of preparing for carrying-in the substrate in an embodiment of the present invention.

FIG. 19B illustrates an F-F′section of FIG. 19A.

FIG. 20A illustrates a plan view showing the positional relation of the substrate and the peripheral members immediately before substrate-placing in an embodiment of the present invention.

FIG. 20B illustrates a G-G′ section of FIG. 20A.

FIG. 21 illustrates the positional relation of the substrate and the peripheral members immediately after substrate-placing in an embodiment of the present invention.

FIG. 22 illustrates the positional relation of the substrate and the peripheral members at completion of carrying-in of the substrate and at completion of preparation for carrying-out thereof in an embodiment of the present invention.

FIG. 23 illustrates the positional relation of the substrate and the peripheral members at the heating position in an embodiment of the present invention.

FIG. 24 illustrates the positional relation of the substrate and the peripheral members at the cooling position in an embodiment of the present invention.

FIG. 25A illustrates a plan view showing the substrate-holding member having projections for the respective substrate-supporting parts in an embodiment of the present invention.

FIG. 25B illustrates an H-H′ section of FIG. 25A.

FIG. 26A illustrates the substrate-supporting part in an open-ring shape in an embodiment of the present invention.

FIG. 26B illustrates the substrate-supporting part in an open-ring shape in an embodiment of the present invention.

### DESCRIPTION OF EMBODIMENTS

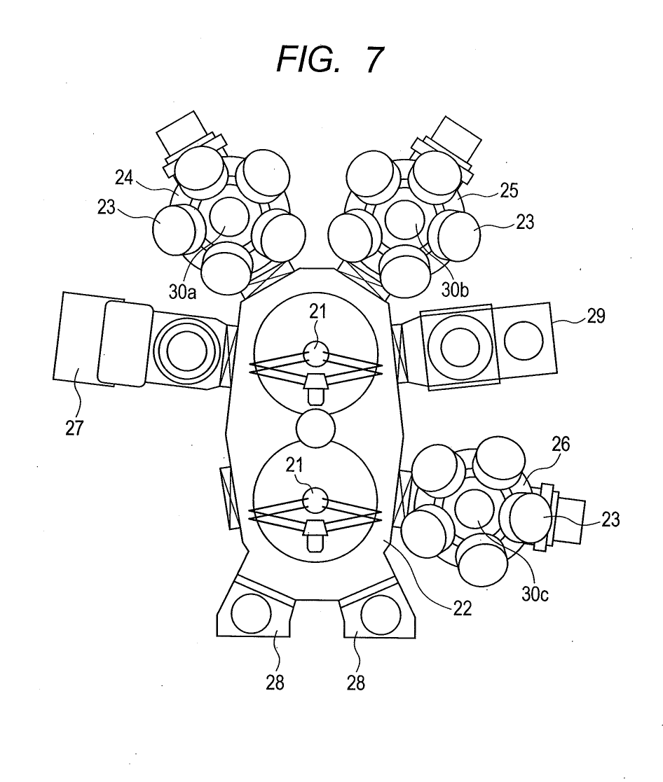

The embodiments of the present invention will be described below in detail referring to the drawings. In the drawings given below, the parts having the same function are represented by the same reference numeral, and repeated description thereof is not given. Other than FIGS. 7, 8, 18, 26A and 26B, a part of the hatching is eliminated in cross sections of the drawings for easy understanding of drawing.

### First Embodiment

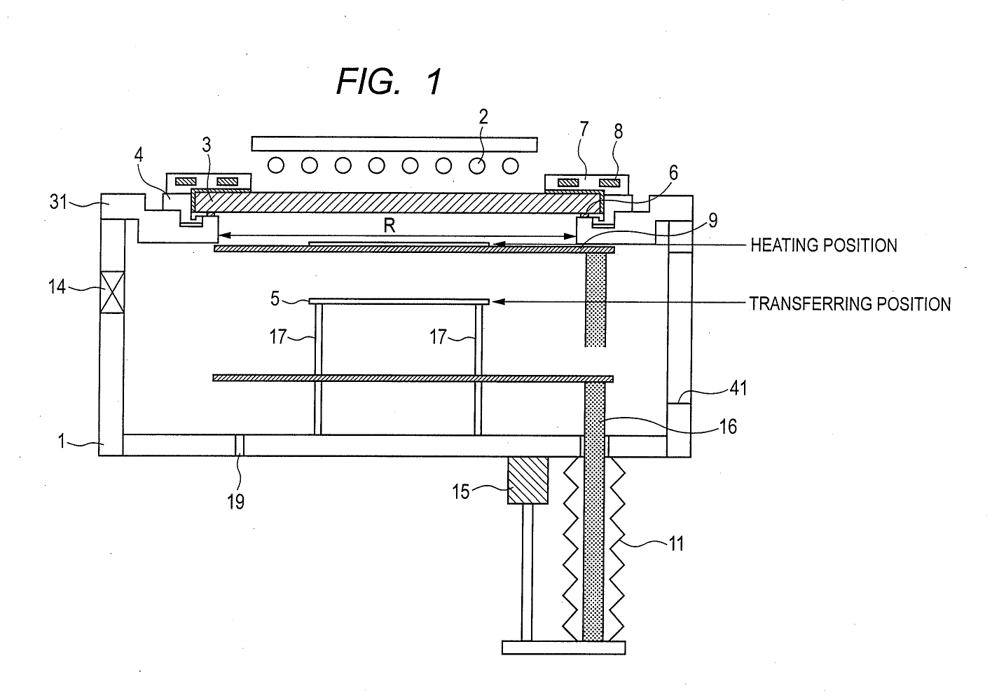

FIG. 1 illustrates the structure of vacuum heating and cooling apparatus according to the first embodiment.

In FIG. 1, a vacuum chamber 1 has a quartz window 3 fixed thereto at upper portion thereof using a vacuum-seal member (not shown), the window 3 allowing heating light coming from a halogen lamp 2 to penetrate therethrough. The vacuum-seal member is preferably a highly heat resistant O-ring such as Viton (trade mark) and Kalrez (trade mark). The quartz window 3 functions as an incidence part for causing the heating light generated from the halogen lamp 2 to enter the vacuum chamber 1. The outer shape R of the incidence part is, however, not defined by the outer shape of the quartz window 3, but is defined by the outer shape of the incidence part viewed from inside the vacuum chamber 1, or according to the example of FIG. 1, by the hole shape of a member 31 supporting the quartz window 3. As illustrated in FIG. 1, when a quartz window mounting and dismounting ring 4 is located between the vacuum chamber 1 and the quartz window 3, the mounting and dismounting of the quartz window 3 becomes easy. The size of the incidence part is preferably selected to 1.5 times or larger than the size of a substrate 5, and, according to the first embodiment, the diameter of the incidence part is selected to 340 mm with respect to the diameter of 200 mm of the substrate. The halogen lamp 2 as the radiation energy source emitting the heating light is positioned at atmosphere side. That is, the halogen lamp 2 is positioned at outside the vacuum chamber 1 so as to irradiate the incidence part with the heating light. The radiation energy source is not limited to the halogen lamp 2 if only the source emits heating light such as infrared light. There is positioned a ring-shaped light-shielding plate 7 between the halogen lamp 2 and the quartz window 3 in order not to directly irradiate an O-ring 6 as the vacuum-seal member with the heating light of the halogen lamp 2. The light-shielding plate 7 is made of aluminum having good thermal conductivity, and has a cooling water passage 8 to form a structure of being cooled by cooling water.

The vacuum chamber 1 below the halogen lamp 2 contains a substrate-holding member 9 having a size larger than that of the incidence part to prevent incidence of heating light into the vacuum chamber. The material of the substrate-holding member 9 is preferably the one easy to absorb infrared light and easy to release heat; although silicon carbide is used in the first embodiment, aluminum nitride can be used. Other than those materials, the substrate-holding member 9 can be formed by: an integrally molded component made mainly of at least one element selected from the group consisting of silicon, carbon, silicon carbide, silicon nitride, aluminum nitride, aluminum oxide, and titanium carbide, or a compound thereof; an assembly of a laminated metal substrate with a plate made mainly of above element or compound thereof; or a substrate-holding member made of above integrally molded component coated with a metal film on one surface thereof. The material of above metal substrate and above metal film can be at least one metal selected from the group consisting of gold, silver, copper, aluminum, titanium, vanadium, chromium, iron, cobalt, nickel, zinc, zirconium, niobium, molybdenum, ruthenium, rhodium, palladium, tin, hafnium, tantalum, tungsten, iridium, and platinum, an alloy made mainly thereof, or a compound made mainly thereof.

The substrate-holding member 9 is supported by at least one supporting rod 16, and the supporting rod 16 is connected with a vertical-drive mechanism 15 positioned at atmosphere side via a bellows 11, thus the vertical-drive mechanism 15 drives the supporting rod 16 in the vertical direction. The vertical-drive mechanism 15 may be a motor-drive type or an air-cylinder drive type using compressed air. The vertical-drive mechanism 15 is connected with a control part (not shown in FIG. 1) described later, and the control part controls the drive of the vertical-drive mechanism 15, thus controlling the rise and fall (up and down) of the supporting rod.

A gate valve 14 for transferring the substrate is positioned on a side surface of the vacuum chamber 1 to allow carrying-in and carrying-out of the substrate 5 to and from adjacent vacuum chamber while maintaining the vacuum. At opposite side of the gate valve 14 for transferring the substrate in the vacuum chamber 1, an evacuation opening 41 is located to conduct evacuation of the vacuum chamber 1, and a vacuum pump for evacuation (not shown) can be installed thereat via a gate valve for vacuum sealing (not shown).

The vacuum chamber 1 is fabricated by aluminum or stainless steel having low gas-release rate, and the chamber at atmosphere side is wound with a sheath-heater for baking (not shown) and a cooling water pipe for cooling (not shown) therearound. When the vacuum chamber 1 is evacuated from the atmospheric pressure, electric power is applied to the sheath-heater to heat the vacuum chamber 1 to 150° C. or higher temperature to conduct baking for at least 2 hours, thus enhancing the gas-release from inside wall of the chamber. After completing the chamber baking, water is introduced to the cooling water pipe to cool the chamber to room temperature. When the vacuum in the vacuum chamber 1 reaches a saturation level, the preparation completes. However, the cooling water is continued to flow in order to prevent warming of the vacuum chamber 1 during the heating step. A gas inlet 19 is opened at least one position of the vacuum chamber 1.

Next is the description about the operation from the heating to cooling (natural cooling) of the substrate to the carrying-out of the substrate from the vacuum chamber in the first embodiment referring to the drawings.

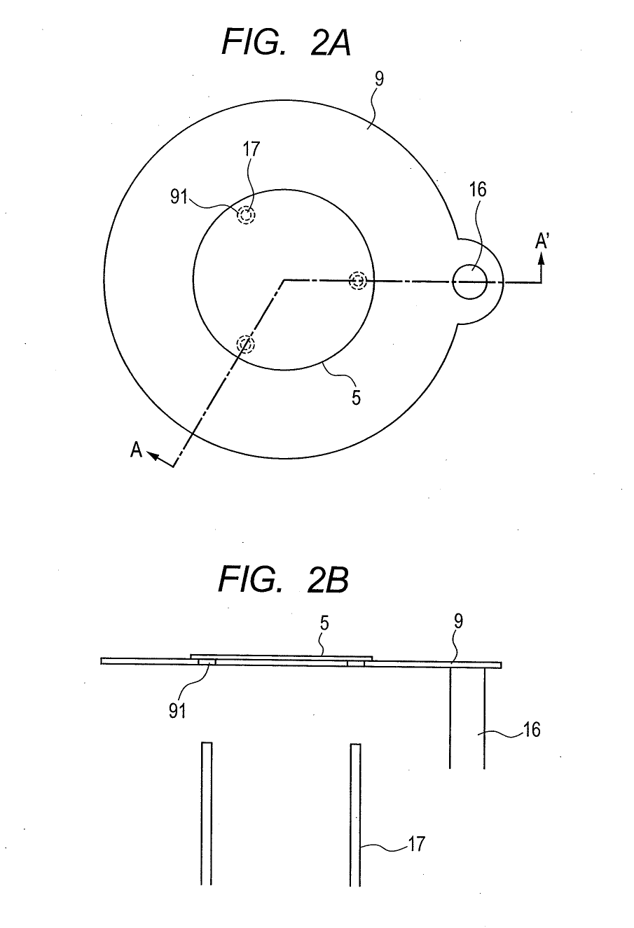

As illustrated in FIGS. 2A and 2B, during the heating step the vertical-drive mechanism (given in FIG. 1) ascends the substrate-holding member 9 above the front end of a push-up pin 17 to position the substrate-holding member 9 at a distance of within 100 mm from the halogen lamp in a state that the substrate 5 is placed on the substrate-holding member 9. The position is defined as the “heating position”. On heating the substrate, power is applied to the halogen lamp to irradiate the substrate 5 with heating light from atmosphere side via the quartz window 3. The diameter of the substrate-holding member 9 is designed to be slightly larger than that of the incidence part, and thus the substrate-holding member 9 can block the heating light. As a result, there can be suppressed the effect of temperature increase with time by the heating light at the members below the substrate-holding member 9 inside the chamber and at the chamber itself. According to the first embodiment, the heating light-shielding effect is attained by selecting the diameter of the substrate-holding member 9 to 360 mm with respect to the diameter of 340 mm of the incidence part.

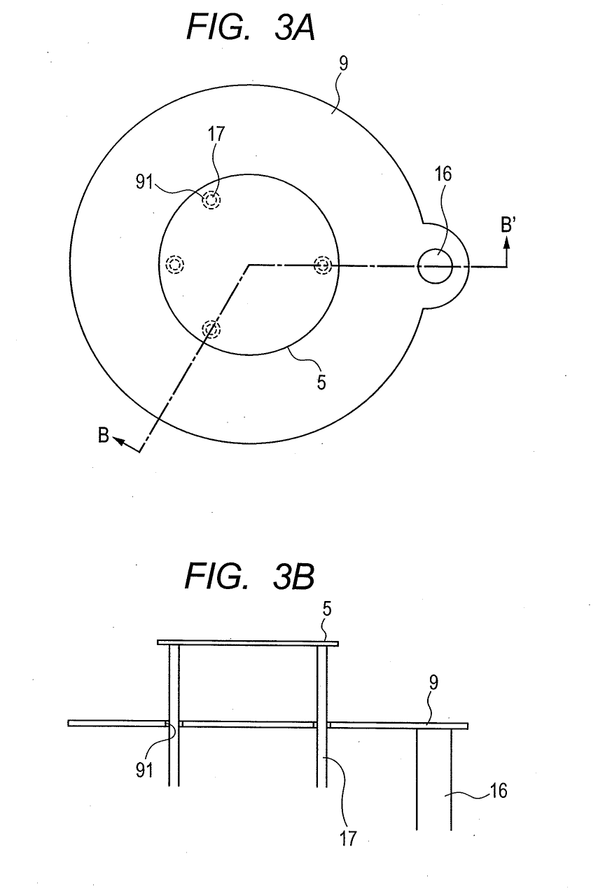

In not-heating state, the substrate-holding member 9 is descended to bring the substrate 5 apart from the halogen lamp. At this moment, by positioning the push-up pin 17 at the bottom surface of the vacuum chamber 1 (shown in FIG. 1) so that the substrate may be carried-in and carried-out by pick-and-place action of a substrate-transfer hand, the substrate can be transferred onto the push-up pin. Among the non-heating positions, the special position allowing transferring the substrate is defined as the “transferring position”. Further detail of the transferring position is described below referring to FIGS. 3A and 3B. The transferring position is the position where the substrate-holding member 9 is moved to below the front end of the push-up pin 17 and then the substrate is transferred onto the push-up pin. Since a hole 91 is opened on the substrate-holding member 9 to allow the pin to penetrate therethrough, the substrate-holding member 9 can be descended without colliding against the push-up pin 17. According to the first embodiment, three push-up pins are arranged along a pitch circle having pitch circle diameter of 180 mm with equal spacing therebetween, and three through-holes for the respective push-up pins to penetrate therethrough are arranged on the substrate-holding member 9 with the same pitch circle diameter as that of the push-up pins with equal spacing therebetween.

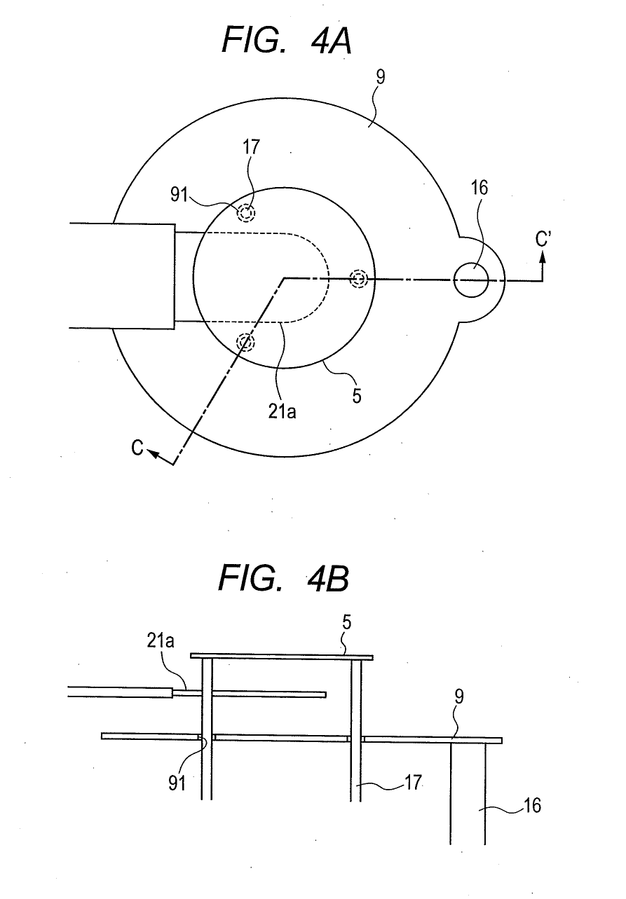

FIGS. 4A and 4B illustrate the state that a substrate-transfer hand 21a passes through an opened gate valve (not shown in FIGS. 4A and 4B) and positions at directly below the substrate which is positioned at the substrate-transferring position, or the state of immediately before picking-up the substrate. Three push-up pins 17 are arranged so as to avoid the track of the substrate-transfer hand 21a, thus not to bring the substrate-transfer hand 21a collide against the push-up pin 17. As illustrated in FIGS. 3A and 3B and FIGS. 4A and 4B, in a state that the substrate is placed on the front end of the push-up pin 17, which is the non-heating position, the substrate waits for a specified cooling time before being transferred to outside the vacuum chamber 1, and thus the substrate is subjected to natural cooling. By separating the substrate from the substrate-holding member 9, and by transferring the substrate onto the push-up pin 17 which is positioned at the non-heating position, the thermal conduction between the substrate-holding member 9 and the substrate can be avoided, thus increasing the cooling effect mutually.

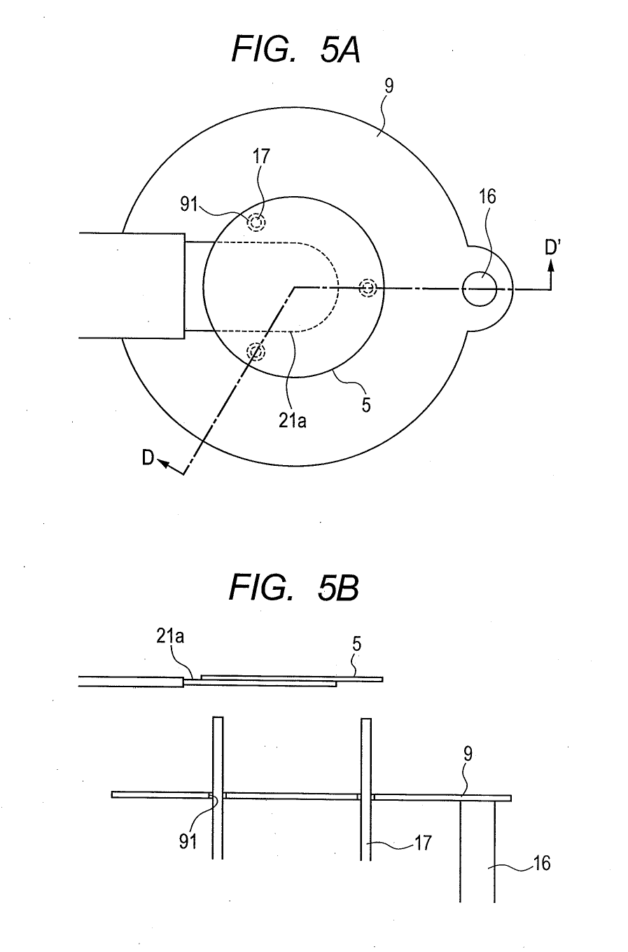

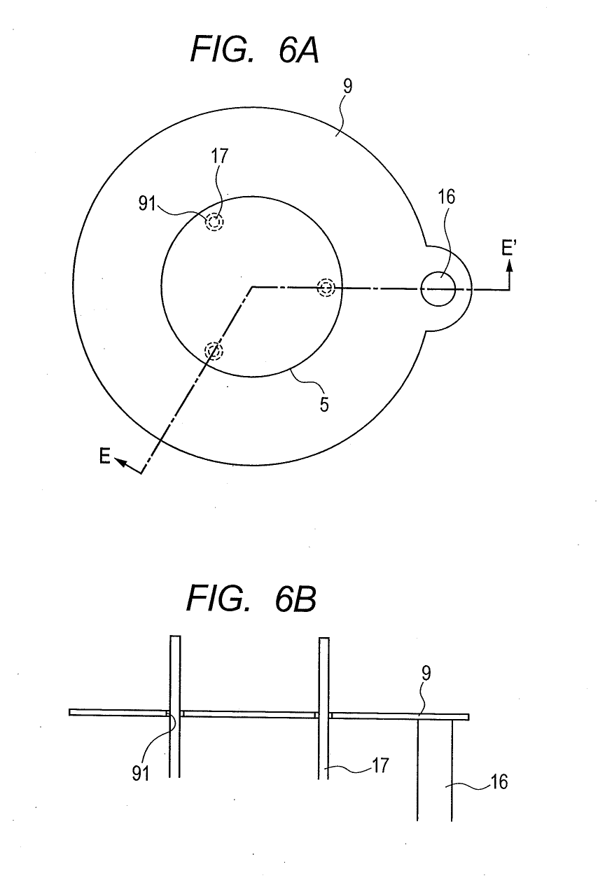

FIGS. 5A and 5B illustrate the positional relation of the substrate and the peripheral members immediately after picking-up the substrate. By moving the substrate-transfer hand 21a to above the front end of the push-up pin 17, the substrate is transferred from on the push-up pin 17 onto the substrate-transfer hand 21a. FIGS. 6A and 6B illustrate a state after the substrate-transfer hand 21a having the substrate placed thereon passes through the gate valve 14 and is carried-out from the vacuum chamber 1. The flow of operation from the carrying-in to the start of heating of the substrate can be done by reversing the flow of carrying-out the substrate illustrated in FIG. 2A to FIG. 6B, which is given by an order of from FIG. 6B to FIG. 2A.

FIG. 7 illustrates the structure of the chamber of the sputtering apparatus joined with a vacuum heating and cooling apparatus in the first embodiment. The sputtering apparatus shown in FIG. 7 is a manufacturing apparatus which can form, in a vacuum throughout manufacturing, a magnetoresistance element and a semiconductor element having a three-layer structure containing at least a magnetization fixed layer, a tunnel barrier layer or a non-magnetic conductive layer, and a magnetization free layer.

The sputtering apparatus illustrated in FIG. 7 includes a vacuum-transfer chamber 22 having two vacuum-transfer mechanisms (robots) 21. The vacuum-transfer chamber 22 is connected to three sputter deposition chambers 24, 25, and 26, having a plurality of sputtering cathodes 23 mounted therein, an etching chamber 27 for cleaning the surface of the substrate, load-lock chambers 28 for carrying-in and carrying-out the substrate between atmosphere and vacuum, and a vacuum heating and cooling apparatus 29 of the first embodiment shown in FIG. 1, via the respective gate valves. With the structure, transfer of the substrate between chambers can be done without breaking the vacuum. The sputter deposition chambers 24 to 26 have the substrate holders 30a to 30c, respectively. The vacuum-transfer chamber 22 may have an oxidation treatment chamber.

According to the first embodiment, the sputter deposition chamber 24 has targets of Ta, Ru, IrMn, CoFe, and CoFeB mounted therein, and the sputter deposition chamber 25 has at least MgO target mounted therein, and the sputter deposition chamber 26 has at least CoFeB target and Ta target mounted therein. Using the vacuum-transfer mechanism 21, the Si substrate is transferred from the load-lock chamber 28 into vacuum. First in the etching chamber 27, impurities adhering onto the Si substrate are removed. After that, the vacuum-transfer mechanism 21 transfers the Si substrate to the sputter deposition chamber 24 to form a film of laminate of Ta (5 nm)/Ru (2 nm)/IrMn (6 nm)/CoFe (2.5 nm)/Ru (0.85 nm)/CoFeB (3 nm) on the Si substrate. Then, the vacuum-transfer mechanism 21 transfers the Si substrate from the sputter deposition chamber 24 to the sputter deposition chamber 25, which forms a film of MgO with about 1 nm of thickness on the laminate, thus forming the structure of Si substrate/Ta (5 nm)/Ru (2 nm)/IrMn (6 nm)/CoFe (2.5 nm)/Ru (0.85 nm)/CoFeB (3 nm)/MgO (1 nm). Next, the vacuum-transfer mechanism 21 transfers the Si substrate from the sputter deposition chamber 25 to the vacuum heating and cooling apparatus 29, which applies heating and cooling treatment to the transferred Si substrate (substrate 5) while transferring it. Finally, the vacuum-transfer mechanism 21 transfers the Si substrate from the vacuum heating and cooling apparatus 29 to the sputter deposition chamber 26, which laminates CoFeB (3 nm)/Ta (5 nm) on the laminate formed on the transferred Si substrate, thus completing the manufacture of the tunnel magnetoresistance element.

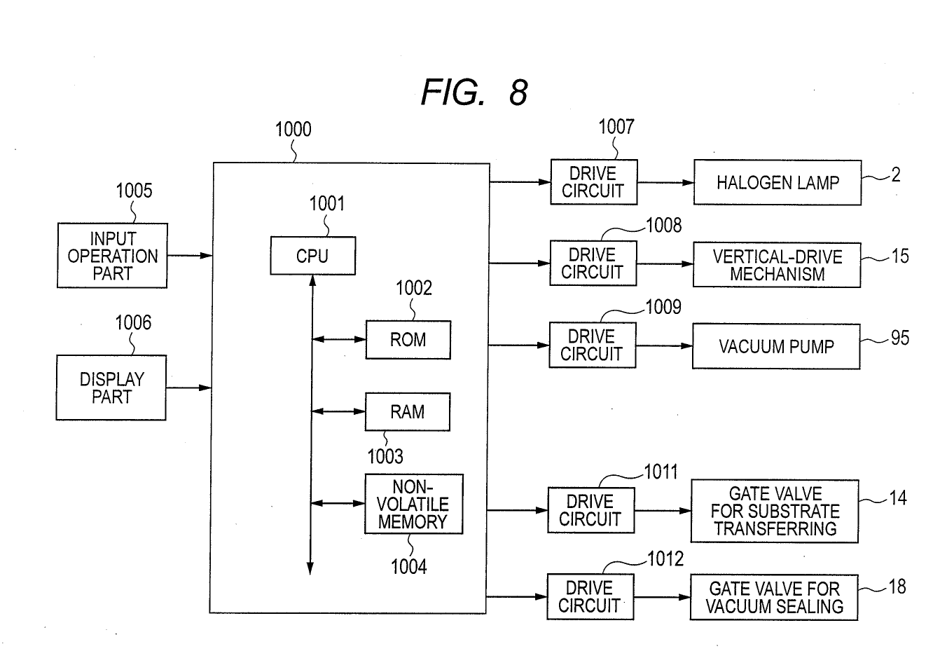

Next is the detail description about the treatments conducted in the vacuum heating and cooling apparatus 29 illustrated in FIG. 1 of the first embodiment referring to FIG. 8.

On receiving an instruction of heating and cooling treatment, a control part 1000 conducts control of opening the gate valve 14 for transferring the substrate. At this moment, the substrate 5 on which up to the MgO film was formed in the sputter deposition chamber 25 is transferred by the substrate-transfer mechanism 21 of the vacuum-transfer chamber 22 onto the push-up pin 17 which is waited at the transferring position in the vacuum heating and cooling apparatus 29. After that, the gate valve 14 is closed by the control of the control part 1000. At this moment, the control part 1000 controls the vertical-drive mechanism 15 to transfer the substrate 5 held by the push-up pin to the substrate-holding member 9, and to ascend the substrate-holding member 9 so that the substrate 5 is positioned at the heating position. In this action, the heating position is preferably set so that the distance between the halogen lamp 2 and the substrate 5 is 100 mm or less. In this state, according to an instruction of the control part 1000, electric power is applied to the halogen lamp 2 to irradiate the substrate 5 with the heating light from the atmosphere side through the quartz window 3. By setting the diameter of the substrate-holding member 9 to be slightly larger than that of the incidence part, the substrate-holding member 9 can block the heating light. As a result, there can be suppressed the effect of temperature increase with time by the heating light at the members below the substrate-holding member 9 inside the chamber and at the chamber itself. According to the first embodiment, the heating light shielding effect is attained by setting the diameter of the substrate-holding member 9 to 360 mm with respect to the diameter of 340 mm of the incidence part. When the temperature of the substrate 5 reaches a desired level, the control part 1000 decreases the electric power supplied to the halogen lamp 2 to perform the control so that the substrate keeps a certain temperature. The heat treatment of the substrate is thus conducted.

After a desired time has passed, the control part 1000 performs the control to stop electric power supply to the halogen lamp 2. Then, the control part 1000 controls the vertical-drive mechanism 15 to descend the substrate-holding member 9 which supports the substrate 5 subjected to the heat treatment, and transfers the substrate 5 onto the push-up pin 17. That is, the substrate 5 moves to the transferring position and preparation for transfer is conducted. Then, the control part 1000 opens the gate valve 14 to let the substrate-transfer hand of the substrate-transfer mechanism 21 carry-out the substrate 5 on the push-up pin 17.

In this procedure, in the heat treatment, the control part 1000 controls the drive of the substrate-holding member 9 so that the substrate 5 is positioned at the heating position, stops the substrate 5 at the heating position, and conducts the heat treatment. Then, on carrying-out the substrate, the control part 1000 controls the drive of the substrate-holding member 9 so that the substrate 5 is positioned at the transferring position, stops the substrate 5 at the transferring position, and prepares for the substrate transfer.

As described above, in the first embodiment, the substrate-holding member 9 can block the heating light by designing the diameter of the substrate-holding member 9 to be slightly larger than that of the incidence part. As a result, in a vacuum heating and cooling apparatus which can conduct rapid heating and rapid cooling of the substrate after deposition treatment while maintaining high vacuum condition, the temperature rise of the members in the chamber with time can be suppressed, and the temperature variation between substrates can be decreased.

### Second Embodiment

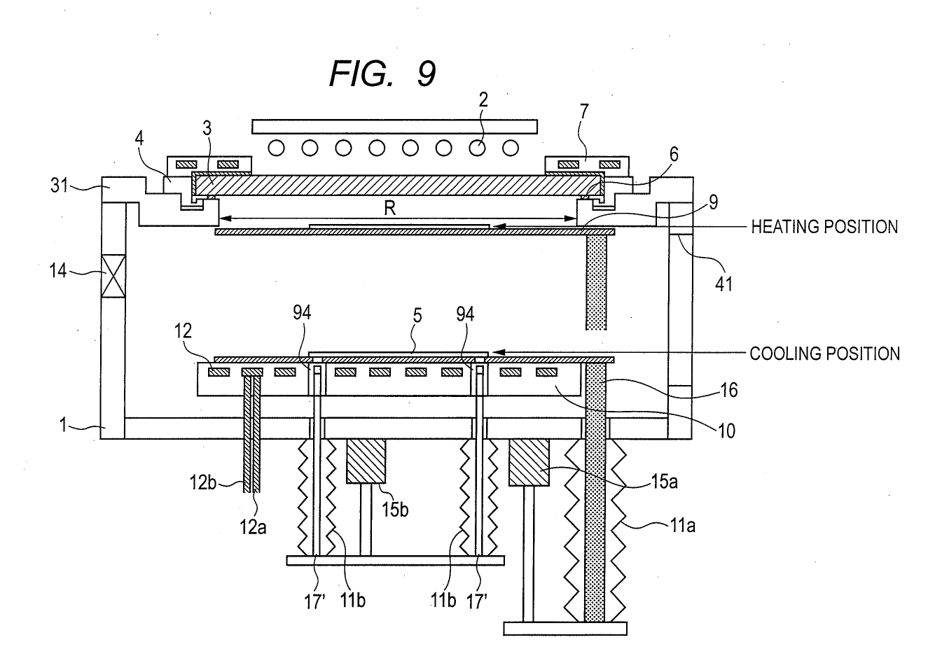

According to the first embodiment, the temperature of substrate 5 and substrate-holding member 9 after the heat treatment decreases naturally with time. However, a long time may be required to reach the room temperature level. Regarding the substrate, it can be carried-out at a high temperature. For the substrate-holding member 9, however, when a next substrate is carried-in while the temperature of the substrate-holding member 9 is not sufficiently decreased, the thermal conduction from the substrate-holding member 9 may vary the initial temperature of the substrate before the irradiation with the heating light. For the case of successive heat treatment of substrate, the effect of accumulation of heat with time in the substrate-holding member 9 induces temperature variation among substrates, which may result in poor production yield. To prevent or decrease the accumulation of heat with time in the substrate-holding member 9, in the second embodiment, a cooling member 10 is positioned at lower part in the vacuum chamber 1, as illustrated in FIG. 9, and the cooling member 10 has through holes 94 each for penetrating a push-up pin 17′ therethrough, and further the push-up pins 17′ are connected and arranged with a vertical-drive mechanism 15b separate from a vertical-drive mechanism 15a of the substrate-holding member 9. The cooling member 10 contains a cooling water passage 12 to be a flow passage of cooling water as the coolant, and is connected to at least a pair of a cooling water inlet 12a and a cooling water outlet 12b, thus allowing introducing the cooling water from atmosphere side. Although not illustrated in FIG. 9, the cooling water inlet 12a and the cooling water outlet 12b are connected to a cooling apparatus such as chiller via a pump to circulate and supply the cooling water regulated to a specified temperature. The pump (not shown) is connected to the control part 1000 and is driven by an instruction of the control part 1000.

The cooling member 10 is preferably made of a material with low gas-release rate and high thermal conductivity; the second embodiment uses aluminum.

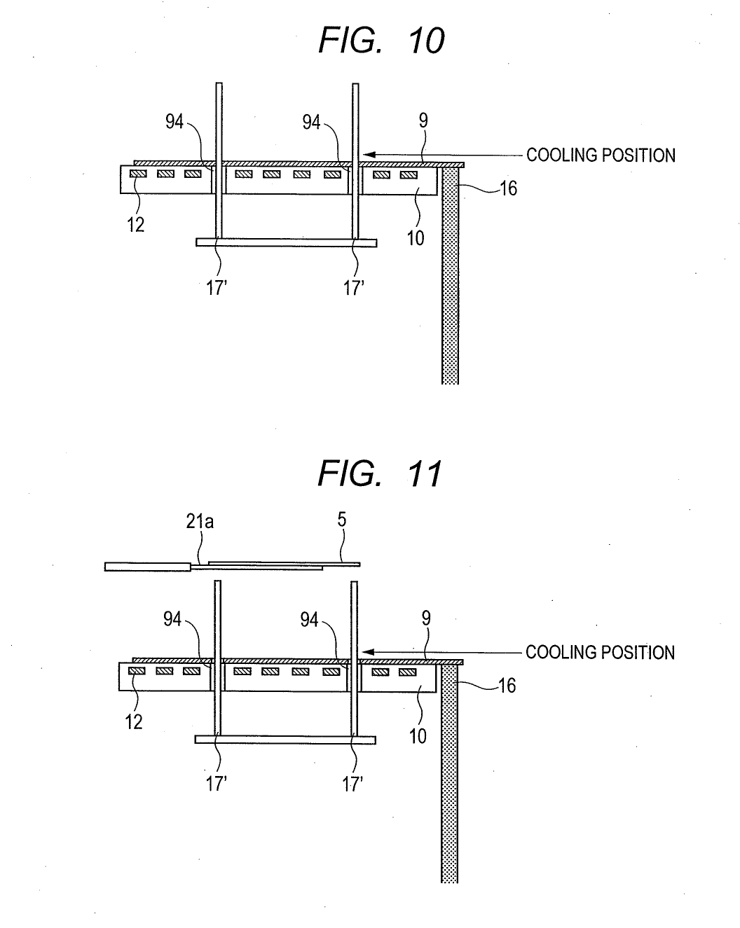

Next is the description about the procedure of carrying-in, heating, cooling, and carrying-out the substrate according to the second embodiment referring to the drawings. FIG. 10 illustrates the positional relation of the push-up pin 17′ and the substrate-holding member 9 in a state of preparation for carrying-in before carrying-in the substrate. In this state, the substrate-holding member 9 contacts the cooling member 10 and is cooled. When the push-up pin 17′ for receiving the substrate ascends, the gate valve (not shown) is opened to complete the preparation for carrying-in the substrate.

Then, the vacuum-transfer robot transfers the substrate from adjacent vacuum-transfer chamber into the vacuum heating and cooling apparatus. FIG. 11 illustrates the positional relation of the peripheral members on carrying-in the substrate, showing the state that the substrate 5 on the substrate-transfer hand 21a is moved directly above the push-up pin 17′. After that, the substrate-transfer hand 21a descends below the front end of the push-up pin 17′, thus transferring the substrate 5 onto the push-up pin 17′. Furthermore, the substrate-transfer hand 21a draws back into the vacuum-transfer chamber, the gate valve closes, and then the substrate carrying-in operation is completed.

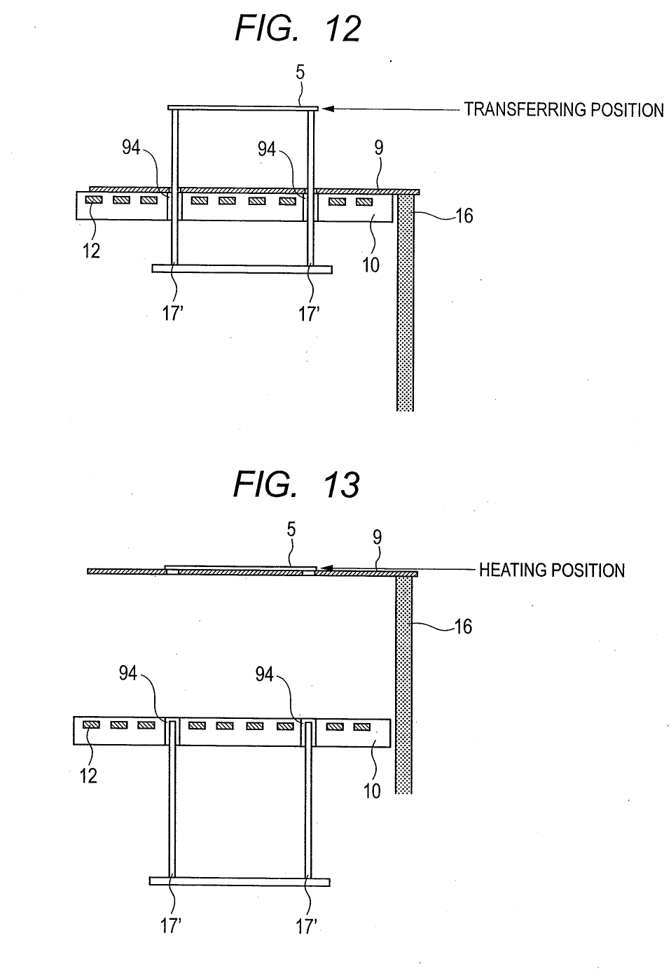

FIG. 12 illustrates the state of completing the substrate carrying-in action. The position of the substrate at this moment is at a special position of the transferring position in the non-heating position.

Next is the description about the operation until reaching the heating position. First, the substrate-holding member ascends to above the front end of the push-up pin 17′, receives the substrate on the push-up pin 17′, and then further ascends and stops at a position within 100 mm from the halogen lamp 2. This position is the heating position. After that, the push-up pin 17′ descends, and stops when the front end of the push-up pin 17′ becomes at or below the level of the surface of the cooling member 10, thus completing the preparation for heating. FIG. 13 illustrates the positional relation of the substrate and the peripheral members when preparation for heating is completed and heating is possible, that is, at the heating position.

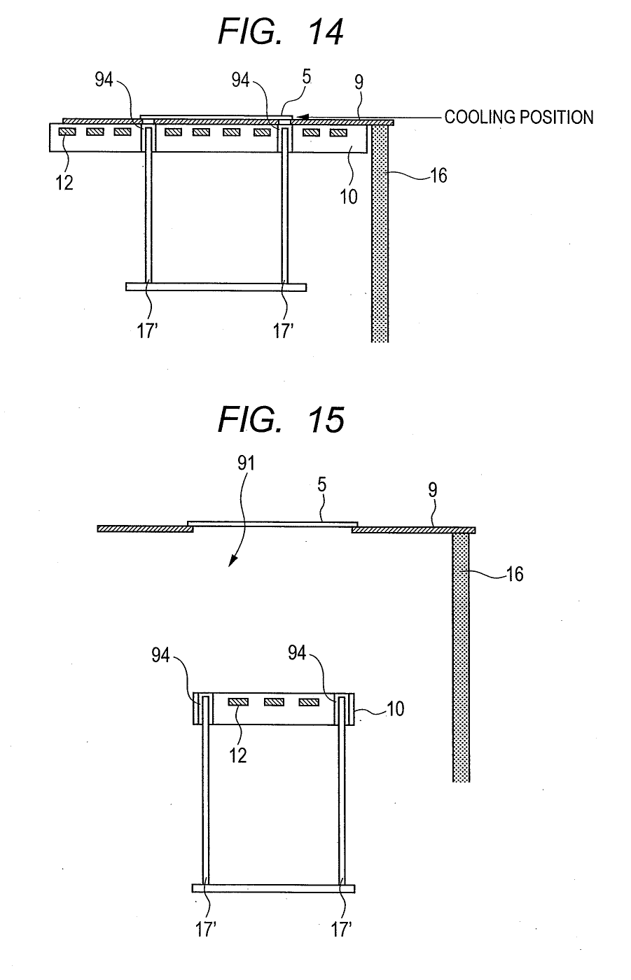

After completing the heating step, the substrate-holding member 9 descends down until contacting the cooling member 10 while having the substrate 5 placed thereon. The position of the substrate at this moment is a special position of cooling position in the non-heating positions (FIG. 14). In this state, the substrate 5 is indirectly cooled by the cooling member 10 via the substrate-holding member 9. When the heating temperature is high or depending on the kind of the substrate 5, on initiating the rapid cooling under the contact of the substrate-holding member 9 with the cooling member 10, the thermal shock may generate crack on the substrate. To prevent the crack of the substrate, the second embodiment does not descend the substrate-holding member 9 without stopping after completing the heating step down to the cooling position contacting the cooling member 10, but once stops the substrate-holding member 9 at an interim position between the transferring position and the cooling position. That specific interim position is preferably more close to the cooling member 10, and preferably within 20 mm above the cooling member 10. After allowing the substrate 5 to stand at the cooling position until the temperature decreases to a desired temperature or below, only the push-up pin 17′ is ascended to move the substrate 5 to the transferring position, thus completing the preparation for transfer, (FIG. 12).

With the procedure, the substrate-holding member 9 can maintain the cooling state in contact with the cooling member 10 until next substrate arrives, and thus the effect of accumulation of heat of the substrate-holding member 9 on the next substrate can be suppressed, which can decrease the variation of temperature between substrates. The structure may be the one to cool only the substrate-holding member 9.

### Third Embodiment

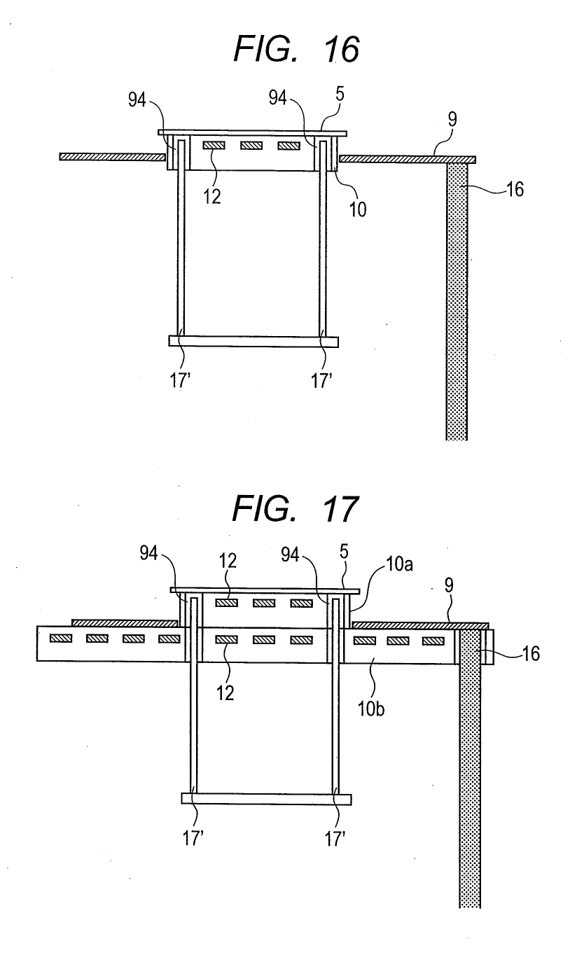

During cooling step of the second embodiment, the substrate 5 is indirectly cooled by the cooling member 10 via the substrate-holding member 9. According to the third embodiment, for further increasing the cooling speed of the substrate, the substrate 5 is contacted with and placed directly on the cooling member 10 in the cooling step. Hence, the cooling speed can be increased. As illustrated in FIG. 15, the substrate-holding member 9 is in a ring-shape, the outer peripheral part of the substrate 5 is supported by the inner peripheral part of the ring-shaped substrate-holding member 9, and further the diameter of the cooling member 10 is designed to be smaller than the inner diameter of the ring-shaped substrate-holding member 9. More specifically, the inner diameter of the ring-shaped substrate-holding member 9 is set to 196 mm with respect to the diameter of 200 mm of the substrate, thus holding the substrate in a domain of 2 mm of the edge part of the inner peripheral part. Furthermore, the outer diameter of the cooling member 10 is set to 192 mm so as not to interfere with the inner diameter of the ring-shaped substrate-holding member 9. With the structure, as illustrated in FIG. 16, when the substrate-holding member 9 is descended, the cooling member 10 can penetrate through the ring hole 91 of the substrate-holding member 9, and thus the substrate-holding member 9 can descend further below the surface of the cooling member 10. As a result, the substrate 5 is transferred onto the cooling member 10 to be in contact therewith and placed thereon, thereby significantly increasing the cooling speed.

### Fourth Embodiment

In the third embodiment, the cooling member 10 is formed to a convex shape, the diameter at the upper stage part thereof is designed to be smaller than the inner diameter of the ring-shaped substrate-holding member 9, and the diameter at the lower stage part thereof is designed to be larger than the inner diameter of the ring-shaped substrate-holding member 9. The structure allows the substrate-holding member 9 to pass through the upper stage part of the cooling member 10 during cooling step and further allows the substrate-holding member 9 to be contacted with and directly placed on the convex stage surface of the lower stage part. As a result, the substrate-holding member 9 itself can also be cooled efficiently. To further efficiently cool the substrate-holding member 9, the diameter of the lower stage part of the convex cooling member 10 may be designed to be larger than the diameter of the substrate-holding member 9. Specifically, the diameter of the lower stage part of the convex cooling member 10 is set to 400 mm with respect to the diameter of 360 mm of the substrate-holding member. The convex cooling member 10 is not necessarily the integrally molded component, and may have a structure illustrated in FIG. 17, in which at least two members are overlapped vertically with each other; such as a first cooling member 10a having a diameter smaller than the inner diameter of the ring-shaped substrate-holding member 9 and a second cooling member 10b having a diameter larger than the inner diameter of the ring-shaped substrate-holding member 9.

### Fifth Embodiment

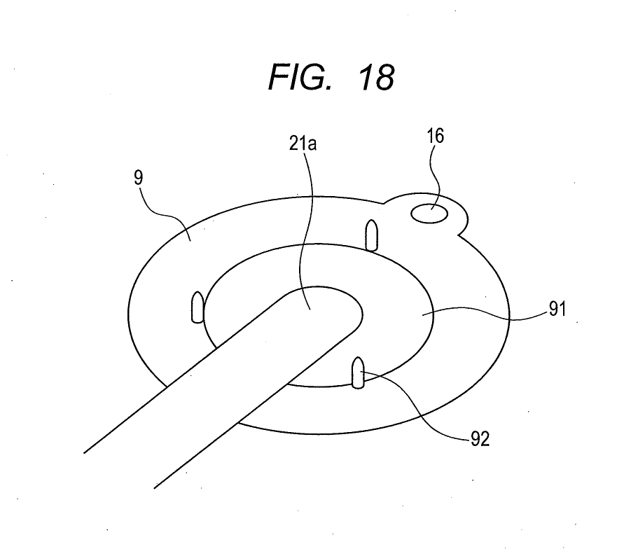

In the fourth embodiment, at least three rod-shaped substrate-supporting parts 92 are erected at edge part of the inner periphery of the ring-shaped substrate-holding member 9 to support the substrate (FIG. 18), which allows carrying-in and carrying-out the substrate by the pick-and-place action without applying the push-up pin for transferring the substrate and without applying the vertical-drive mechanism for the push-up pin. The height of the three substrate-supporting parts 92 mounted on the substrate-holding member 9 is 5 mm or more, preferably 10 mm or more, considering the thickness of the transfer hand and the clearance above and below thereof during extension and shrink thereof, and the height thereof has to be lower than the height of the upper stage part of the cooling member with two-stage structure. According to the fifth embodiment, the height of the substrate-supporting part is designed to 15 mm. Further, the embodiment is devised to use quartz having low thermal conductivity for the substrate-supporting part so as to minimize reverse effect on the temperature distribution in the heated substrate.

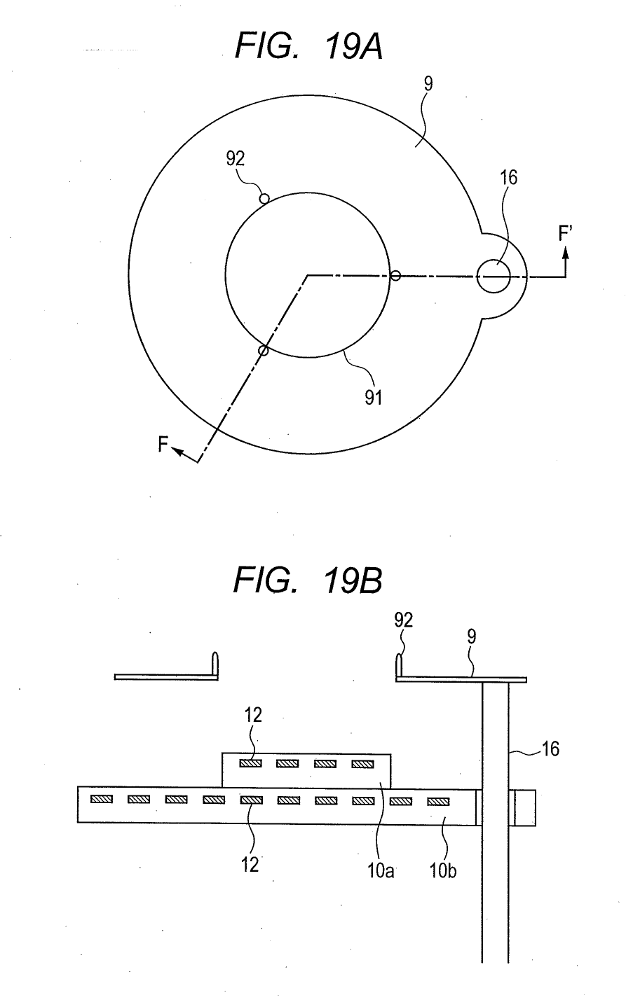

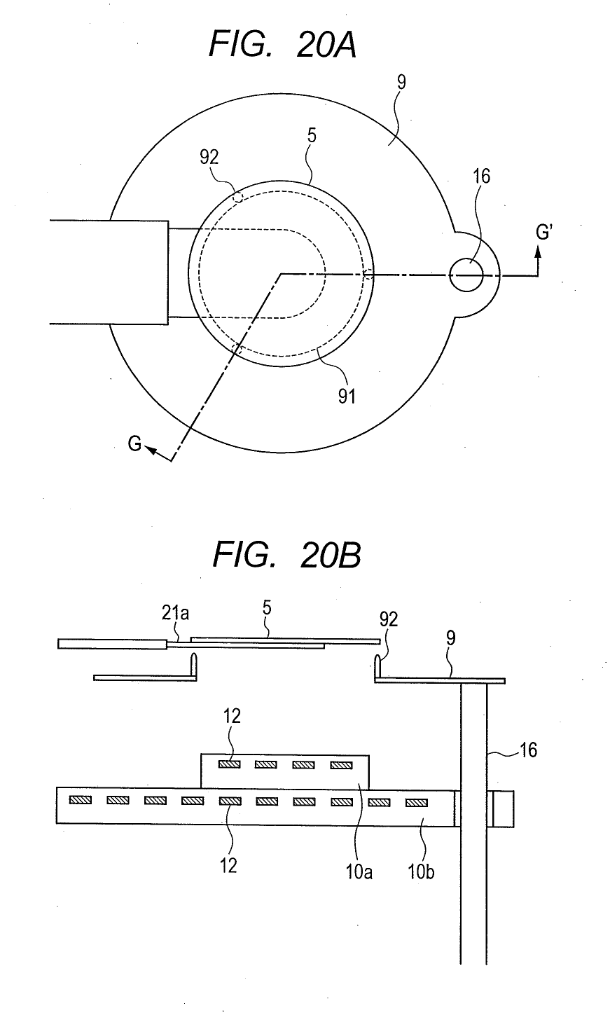

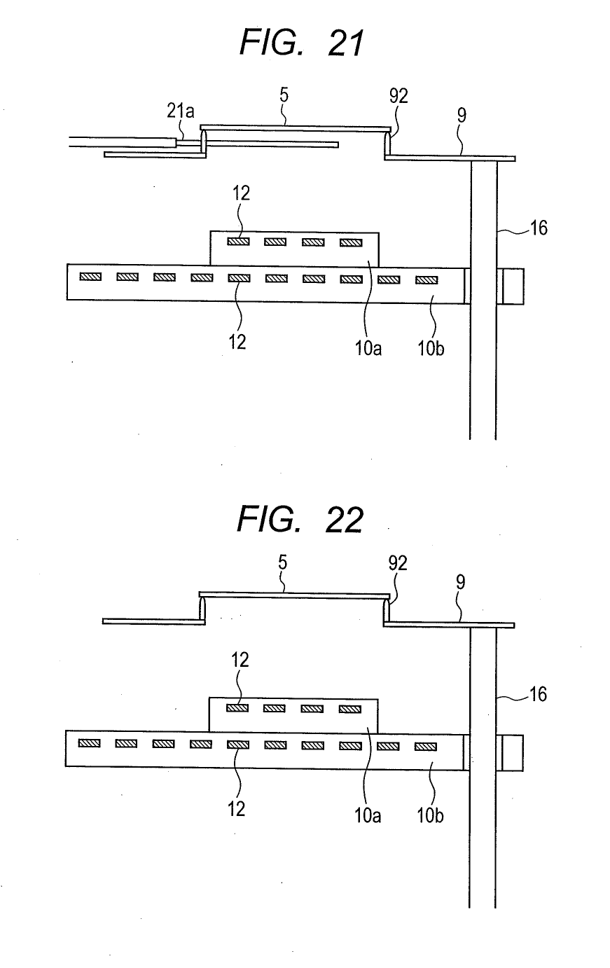

Next is the description about the procedure of carrying-in, heating, cooling, and carrying-out the substrate according to the fifth embodiment referring to the drawings. FIGS. 19A and 19B illustrate the position of the substrate-holding member 9 in a state of preparation for carrying-in. The height of the front end of the three substrate-supporting parts erected on the substrate-holding member 9 at equal spacing therebetween is the same as the height of the center of the opening of the gate valve (not shown) in the vertical direction. Then, the vacuum-transfer robot transfers the substrate from adjacent vacuum-transfer chamber into the vacuum heating and cooling apparatus. FIGS. 20A and 20B illustrate the positional relation of the substrate and the peripheral members immediately before the substrate placing at the substrate carrying-in, showing the state that the substrate 5 on the substrate-transfer hand 21a is moved to directly above the three substrate-supporting parts 92 arranged at equal spacing therebetween. After that, the substrate-transfer hand 21a descends below the front end of the substrate-supporting part 92, thus transferring the substrate 5 onto the substrate-supporting part 92, (FIG. 21).

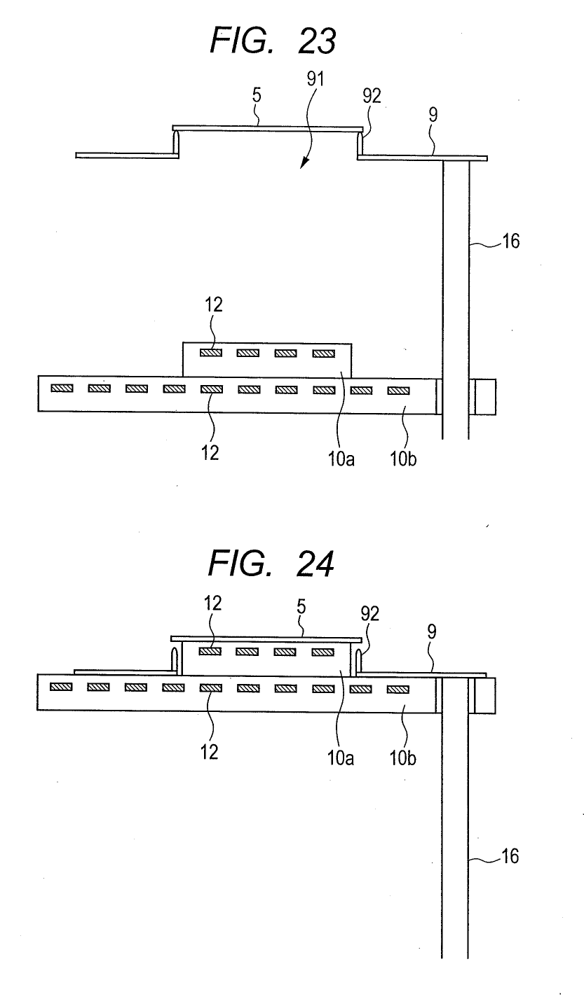

Further the substrate-transfer hand 12a shrinks to return into the vacuum-transfer chamber, the gate valve 14 is closed, and the substrate carrying-in operation is completed (FIG. 22). The position of the substrate 5 at that moment is at a specific position of the transferring position in the non-heating positions. During heating step, the substrate-holding member 9 ascends, and the substrate 5 on the substrate-supporting part 92 stops at a position within 100 mm from the halogen lamp 2 (FIG. 23). The position is the heating position. After completing the heating step, the substrate-holding member 9 descends down until contacting the cooling member 10b at lower stage side of the cooling member having two-stage structure while placing the substrate 5 on the substrate-supporting part 92. Then, the cooling member 10a at the upper stage part penetrates through the hole 91 on the ring-shaped substrate-holding member 9 to above the front end of the substrate-supporting part 92 of the substrate-holding member 9, thus transferring the substrate 5 onto the cooling member 10a of the upper stage part. The position of the substrate at this moment is a special position of cooling position in the non-heating positions (FIG. 24).

When the heating temperature of the substrate is high or depending on the kind of the substrate 5, on initiating the rapid cooling under the contact with the cooling member 10a, the thermal shock may generate crack on the substrate. To prevent the crack of the substrate, in the fifth embodiment, the substrate-holding member 9 does not descend without stopping, after completing the heating step, down to the cooling position contacting the cooling member 10b, but the vertical movement of the substrate-holding member 9 is controlled so that the substrate once stops at an interim position between the transferring position and the cooling position. That specific interim position to enhance the natural cooling is preferably more close to the cooling member 10a, and further preferably within 20 mm above the cooling member 10a. After allowing the substrate 5 to stand at the cooling position until the temperature decreases to a desired level or below, the substrate-holding member 9 is ascended to move the substrate 5 to the transferring position, thus completing the preparation for transfer (FIG. 22).

With the procedure, rapid cooling of the heated substrate can be performed and the cooling state can be maintained, in which the substrate-holding member 9 contacts the cooling member 10b, until next substrate arrives, and thus the effect of accumulation of heat of the substrate-holding member 9 on the next substrate can be suppressed, thereby enabling decrease in the variation of temperature between substrates. Furthermore, elimination of the push-up pin, the vertical-drive mechanism and the bellows thereof can decrease the gas-release sources, and can maintain the high vacuum. In addition, the time of push-up pin action can be shortened in the substrate-transfer time, which improves the throughput. The cooling member may not be used, and the cooling member may cool only one of the substrate and the substrate-holding member.

### Sixth Embodiment

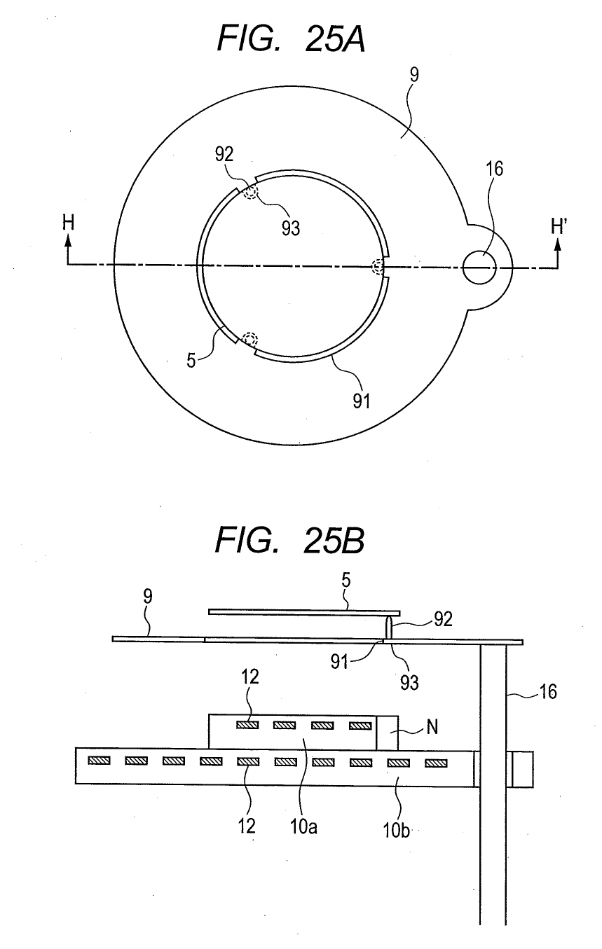

In the fifth embodiment, it is necessary that the inner diameter of the ring-shaped substrate-holding member 9 is designed to be larger than the diameter of the substrate, while bringing the pitch circle diameter of each of the three substrate-supporting parts to be smaller than the diameter of the substrate in order to support the substrate. Thus, the substrate-supporting part may have a shape in which projection 93 is formed toward the inner periphery of the substrate-holding member 9 as illustrated in FIGS. 25A and 25B. In this case, the cooling member 10a has three notches N to avoid interference between the projections 93. Also the structure attains similar effect to that of the fifth embodiment. The inner diameter of the hole 91 of the substrate-holding member 9 is preferably set to 10 mm or less outward from the outer peripheral end part of the substrate in order to prevent or decrease the leak of the heating light.

With the structure, the contact area between the substrate and the cooling member 10a can be increased, thus increasing the cooling speed. Alternatively, the substrate 5 may be directly supported by the projections 93, not forming the substrate-supporting part 92 on the projection 93. In that case, there is needed a push-up pin. Since, however, the contact between the substrate-holding member 9 and the substrate 5 can be decreased, the thermal conduction between members during heating and cooling can be prevented or decreased, and thus the contact area with the cooling member can be increased.

### Seventh Embodiment

First to sixth embodiments use a substrate-holding member having larger diameter than that of the incidence part to block the heating light, thus suppressing the temperature rise in the members and the wall surface at lower part of the vacuum chamber and decreasing the variation of temperature between substrates caused by accumulated heat with time. When, however, the substrate-holding member is directly exposed to the heating light, the substrate-holding member itself increases the temperature, which may induce the temperature rise in the members and the wall surface at lower part of the vacuum chamber by the heat radiation of the substrate-holding member. To this point, a structural design can eliminate the anxiety, and can further decrease the temperature rise with time in the members in the vacuum chamber. To eliminate the effect of radiation, in the seventh embodiment, the surface not subjected to irradiation of the heating light on the substrate-holding member, or the surface facing downward in the vacuum chamber, is coated with a metal film having low radiation factor, which suppresses the effect. The seventh embodiment uses gold considering the four conditions, low radiation factor, high melting point, high thermal conductivity, and high chemical stability.

### Eighth Embodiment

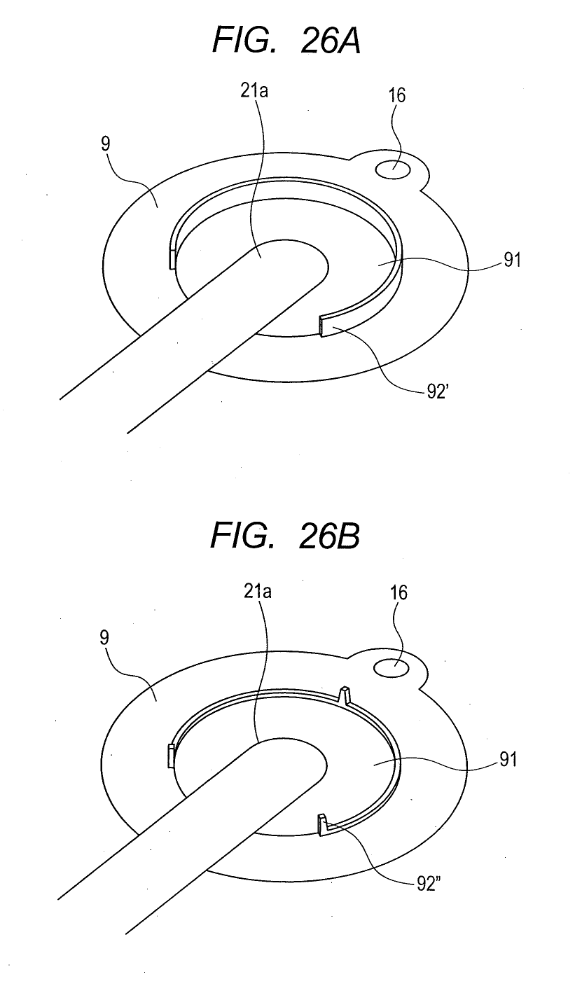

In the fifth embodiment, a substrate-supporting part 92′ mounted on the substrate-holding member 9 is not necessarily a rod-shaped substrate-supporting part, and may be formed into an open-end ring shape in which the substrate-supporting part 92′ has a shape of elongated flat-plate and the flat plate is bent in a long axis direction thereof along the inner periphery end part of the ring-shaped substrate-holding member 9, as illustrated in FIG. 26A. In this case, the width of the open part of the ring is set so as to 100 mm to allow the substrate-transfer hand with 60 mm in width to pass therethrough. To suppress the effect of releasing the heat of the heated substrate to the substrate-supporting part via the contact part to decrease the temperature of the substrate, it is more preferable to cut excess portion of the ring-shape substrate-supporting part 92′ so that a substrate-supporting part 92″ and the substrate contact with each other at only three points, as illustrated in FIG. 26B.

The term “heating position” referred to herein signifies the position at which the substrate should be positioned on heating the substrate, and the heating position is set to a position closer to the radiation energy source than to the non-heating position which is defined below, and specifically within 100 mm of distance between the substrate and the radiation energy source (halogen lamp in the eighth embodiment).

The term “non-heating position” referred to herein signifies the position at which the substrate should be positioned when not heating the substrate, and any position can be selected if only the substrate is distant from the radiation energy source more than from the heating position, specifically at any distance if only the substrate is distant from the radiation energy source by more than 100 mm. Therefore, the transferring position and the cooling position are the non-heating positions, both of which mean special positions of the non-heating position. According to the embodiments, the position to which the substrate 5 is placed on the cooling member 10 is the cooling position.

The term “transferring position” referred to herein signifies the position at which the substrate transferred from outside is firstly held, and which is positioned within the range of the non-heating position. According to the embodiments, the transferring position is set in a space facing the opening of the gate valve 14 for substrate transferring and in a space within a range of the width of the opening of the gate valve 14. In the embodiments 1 to 4, the substrate is held on the front end of the push-up pin, and in the embodiments 5 and 7, the substrate is held on the front end of the substrate-supporting part of the substrate-holding member 9.

1. A heating and cooling apparatus for heating and cooling a substrate in a vacuum, comprising:
a vacuum chamber;
a radiation energy source positioned at the vacuum chamber on an atmosphere side configured so as to emit a heating light;
an incidence part configured so as to cause the heating light from the radiation energy source to enter the vacuum chamber;
a substrate-holding member configured so as to hold the substrate; and
a transfer mechanism configured so as to transfer, in a heating state, the substrate held by the substrate-holding member to a heating position proximal to the radiation energy source, and to transfer, in a non-heating state, the substrate and the substrate-holding member to a non-heating position distant from the radiation energy source,
wherein the substrate-holding member has a plate-like shape for placing the substrate thereon and has an outer shape larger than that of the incidence part for causing the heating light to enter the vacuum chamber.

2. A heating and cooling apparatus according to claim 1, further comprising a separation mechanism configured so as to maintain the substrate held by the substrate-holding member in a state of being separated from the substrate-holding member at the non-heating position.

3. A heating and cooling apparatus according to claim 2, further comprising at least three push-up pins as the separation mechanism being driven between a transferring position to carry-out the substrate from the vacuum chamber and a retract position, and being capable of stopping at the non-heating position,
wherein the substrate-holding member has a hole allowing the push-up pin to penetrate therethrough, and
the apparatus is configured so that the substrate is transferred from the substrate-holding member onto the push-up pin to maintain a state that the substrate and the substrate-holding member are separated from each other at the non-heating position.

4. A heating and cooling apparatus according to claim 1,
wherein the substrate-holding member has an opening at a projection position of the heating light to the substrate held thereon, and
wherein the apparatus further comprises a cooling member being positioned at a non-heating position in the vacuum chamber, having an outer shape capable of penetrating through the opening, and being cooled by a coolant incorporated therein.

5. A heating and cooling apparatus according to claim 1,
wherein the substrate-holding member has a plate part having larger outer shape than that of the incidence part, and a holding part to hold the substrate at a position of incidence part side apart from the plate part.

6. A heating and cooling apparatus for heating and cooling a substrate in a vacuum, comprising:
a vacuum chamber;
a radiation energy source positioned at the vacuum chamber on an atmosphere side configured so as to emit a heating light;
an incidence part configured so as to cause the heating light from the radiation energy source to enter the vacuum chamber;
a substrate-holding member configured so as to hold the substrate;
a transfer mechanism capable of driving the substrate-holding member in a direction toward the incidence part and in a direction away therefrom; and
a cooling member being positioned apart from the incidence part in the vacuum chamber, and being cooled by a coolant incorporated therein,
wherein the substrate-holding member has a shield plate having a larger outer shape than that of the substrate and which can block the incidence of heating light from the incidence part;
the shield plate has an opening at a projection position of the heating light to the substrate held by the substrate-holding member; and
the cooling member has an outer shape capable of penetrating through the opening of the shield plate, and has a cooling surface capable of placing the substrate thereon.

7. A heating and cooling apparatus for heating and cooling a substrate in a vacuum, comprising:
a vacuum chamber;
a radiation energy source positioned at the vacuum chamber on an atmosphere side configured so as to emit a heating light;
an incidence part configured so as to cause the heating light from the radiation energy source to enter the vacuum chamber;
a substrate-holding member configured so as to hold the substrate; and
a transfer mechanism capable of driving the substrate-holding member in a direction toward the incidence part and in a direction away therefrom,
wherein the substrate-holding member has a shield plate having a larger outer shape than that of the substrate and which can block the incidence of heating light from the incidence part, and a holding part to hold the substrate at a position of incidence part side apart from the shield plate.

8. A heating and cooling apparatus according to claim 7,
wherein the shield plate has an opening at a projection position of the heating light to the substrate held by the substrate-holding member.

9. A heating and cooling apparatus according to any of claim 1,
wherein the substrate-holding member is an integrally molded component made mainly of at least one element selected from the group consisting of silicon, carbon, silicon carbide, silicon nitride, aluminum nitride, aluminum oxide, and titanium carbide, or a compound thereof; an assembly of laminated metal substrate with a plate made mainly of above element or compound thereof; or a substrate-holding member made of the above integrally molded component and coated with a metal film on one surface of the substrate-holding member.

10. A heating and cooling apparatus according to claim 9,
wherein the material of the metal substrate and the metal film is at least one metal selected from the group consisting of gold, silver, copper, aluminum, titanium, vanadium, chromium, iron, cobalt, nickel, zinc, zirconium, niobium, molybdenum, ruthenium, rhodium, palladium, tin, hafnium, tantalum, tungsten, iridium, and platinum, an alloy made mainly of the metal, or a compound made mainly thereof.

11. A heating and cooling apparatus according to any of claim 1,
wherein the vacuum chamber includes a gas inlet, through which a gas is introduced.

12. A manufacturing apparatus for forming a magnetoresistance element having a three-layer structure containing at least a magnetization fixed layer, a tunnel barrier layer or a non-magnetic conductive layer, and a magnetization free layer, the apparatus comprising:
a vacuum-transfer chamber including a substrate-transfer mechanism;
a plurality of sputter deposition chambers connected and arranged with the vacuum-transfer chamber via a gate valve;
an oxidation treatment chamber connected and arranged with the vacuum-transfer chamber via a gate valve;
a heating and cooling apparatus according to claim 1, connected and arranged with the vacuum-transfer-chamber via a gate valve; and
a load-lock chamber which is connected and arranged with the vacuum transfer-chamber via a gate valve, and which carries-in and carries-out a substrate from vacuum to atmosphere or from atmosphere to vacuum, and
wherein the manufacturing apparatus is configured so that the magnetoresistance element is formed in a vacuum throughout manufacturing.

13. A manufacturing apparatus for forming a magnetoresistance element having a three-layer structure containing at least a magnetization fixed layer, a tunnel barrier layer or a non-magnetic conductive layer, and a magnetization free layer, the apparatus comprising:
a vacuum-transfer chamber including a substrate-transfer mechanism;
a plurality of sputter deposition chambers connected and arranged with the vacuum-transfer chamber via a gate valve;
an etching chamber connected and arranged with the vacuum-transfer chamber via a gate valve;
a heating and cooling apparatus according to claim 1, connected and arranged with the vacuum-transfer-chamber via a gate valve; and
a load-lock chamber which is connected and arranged with the vacuum transfer-chamber via a gate valve, and which carries-in and carries-out a substrate from vacuum to atmosphere or from atmosphere to vacuum, and
wherein the manufacturing apparatus is configured so that the magnetoresistance element is formed in a vacuum throughout manufacturing.

14. A manufacturing apparatus of a semiconductor element, comprising:
a vacuum-transfer chamber including a substrate-transfer mechanism;
a film-forming chamber connected and arranged with the vacuum-transfer chamber via a gate valve;
a heating and cooling apparatus according to claim 1, connected and arranged with the vacuum-transfer chamber via a gate valve; and
a load-lock chamber which is connected and arranged with the vacuum-transfer chamber via a gate valve, and which carries-in and carries-out a substrate from vacuum to atmosphere or from atmosphere to vacuum, and
wherein the manufacturing apparatus is configured so that a thin film is formed in a vacuum throughout manufacturing.
